(19) United States
(12) Patent Application Publication
(10) Pub. No.: US 2023/0261107 A1
(43) Pub. Date: Aug. 17, 2023

(54) TRANSISTOR GATE STACKS WITH DIPOLE LAYERS

(71) Applicant: Intel Corporation, Santa Clara, CA (US)

(72) Inventors: Abhishek A. Sharma, Hillsboro, OR (US); Tahir Ghani, Portland, OR (US); Wilfred Gomes, Portland, OR (US); Sagar Suthram, Portland, OR (US); Pushkar Sharad Ranade, San Jose, CA (US); Willy Rachmady, Beaverton, OR (US); Ravi Pillarisetty, Portland, OR (US); Anand S. Murthy, Portland, OR (US)

(73) Assignee: Intel Corporation, Santa Clara, CA (US)

(21) Appl. No.: 17/672,332

(22) Filed: Feb. 15, 2022

(51) Int. Cl. H01L 29/78; H01L 29/51; H01L 29/40; H01L 29/06; H01L 29/423; H01L 29/786

(52) U.S. Cl. CPC H01L 29/78391; H01L 29/516; H01L 29/401; H01L 29/7851; H01L 29/0665; H01L 29/42392; H01L 29/78696

(57) ABSTRACT

Disclosed herein are transistor gate-channel arrangements with transistor gate stacks that include dipole layers, and related methods and devices. Transistor gate stacks disclosed herein include a multilayer gate oxide having both a high-k dielectric and a dipole layer. In some embodiments, a thin dipole layer may directly border a channel material of choice and may be between the channel material and the high-k dielectric. In other embodiments, a passivation layer may spontaneously form between the dipole layer and the channel material. In still other embodiments, the high-k dielectric may be between the dipole layer and the channel material. Temporary polarization provided by the dipole layer may increase the effective dielectric constant of the high-k dielectric and may allow to use thinner high-k dielectrics and/or high-k dielectrics of suboptimal quality while maintaining transistor performance in terms of, e.g., gate leakage, carrier mobility, and subthreshold swing.

### BACKGROUND

Transistors may include a gate dielectric between a gate electrode and a semiconducting channel. The gate dielectric may be, for example, a high-k dielectric material.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a cross-sectional side view of a transistor gate-channel arrangement including a transistor gate stack with a dipole layer, in accordance with various embodiments.

FIGS. 2-6 are cross-sectional side views of example single-gate transistors including a transistor gate stack with a dipole layer, in accordance with various embodiments.

FIGS. 7-9 are cross-sectional side views of example double-gate transistors including a transistor gate stack with a dipole layer, in accordance with various embodiments.

FIGS. 10A and 10B are perspective and cross-sectional side views, respectively, of an example fin-based field-effect transistor (FinFET) including a transistor gate stack with a dipole layer, in accordance with various embodiments.

FIGS. 11A and 11B are perspective and cross-sectional side views, respectively, of an example all-around gate transistor including a transistor gate stack with a dipole layer, in accordance with various embodiments.

FIG. 12 is a flow diagram of an example method of manufacturing a transistor gate stack with a dipole layer, in accordance with various embodiments.

FIGS. 13A and 13B are top views of a wafer and dies that include one or more transistor gate stacks with dipole layers in accordance with any of the embodiments disclosed herein.

FIG. 14 is a cross-sectional side view of an integrated circuit (IC) device that may include one or more transistor gate stacks with dipole layers in accordance with any of the embodiments disclosed herein.

FIG. 15 is a cross-sectional side view of an IC device assembly that may include one or more transistor gate stacks with dipole layers in accordance with any of the embodiments disclosed herein.

FIG. 16 is a block diagram of an example computing device that may include one or more transistor gate stacks with dipole layers in accordance with any of the embodiments disclosed herein.

FIG. 17 is a block diagram of an example processing device that may include one or more transistor gate stacks with dipole layers in accordance with any of the embodiments disclosed herein.

### DETAILED DESCRIPTION

Disclosed herein are transistor gate-channel arrangements with transistor gate stacks that include dipole layers, and related methods and devices. The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating transistor gate stacks with dipole layers and associated arrangements (e.g., transistor gate-channel arrangements with dipole layers) and devices (e.g., IC devices implementing transistor gate stacks with dipole layers) as described herein, it might be useful to first understand phenomena that may come into play in certain IC arrangements. The following foundational information may be viewed as a basis from which the present disclosure may be properly explained. Such information is offered for purposes of explanation only and, accordingly, should not be construed in any way to limit the broad scope of the present disclosure and its potential applications.

The performance of a transistor may depend on the number of factors. For example, as described above, some transistors include a gate dielectric, e.g., a high-k dielectric, between a gate electrode and a semiconducting channel material. In such transistors, a stack of a gate dielectric and a gate electrode material is typically referred to as a “transistor gate stack” and careful selection of the gate dielectric is important for optimal performance. Thinner gate dielectrics help increase the gate field and therefore improve the switching ratio of a transistor through better gate control. As is known in the art, the switching ratio is a measure of a ratio of a current (Ion) between source and drain terminals of a transistor when the transistor is supposed to be on and a current (Ioff) between source and drain terminals of a transistor when the transistor is supposed to be off. However, simply reducing the thickness of a gate dielectric leads to increased gate leakage (i.e., a current flowing between a source or a drain terminal and a gate terminal of a transistor). This problem is particularly noticeable at room temperatures because the thermal energy is significantly higher compared to lower-temperature operation and, therefore, trap assisted tunneling, Schottky emission, and other transport modes are active. Operating transistors at lower temperatures may provide some help in that the thermal energy of the carriers may be reduced since the thermal energy is exponentially dependent on the temperature, thus reducing gate leakage, while simultaneously supporting higher mobility due to reduced scattering at lower temperatures and steeper subthreshold swing. Still, even lower operating temperatures cannot sufficiently suppress certain leakage modes such as direct tunneling when using very thin gate dielectrics.

Embodiments of the present disclosure are based on recognition that using an additional dipole layer in a transistor gate stack may help allow using very thin high-k dielectrics (e.g., high-k dielectrics that are thinner than about 1.5 nanometers) while providing improvements in terms of suppressing gate leakage. Transistor gate stacks disclosed herein include a multilayer gate oxide having both a high-k dielectric and a dipole layer. As used herein, a “dipole layer” refers to a layer of a relatively highly polarizable material, i.e., a material having pairs of equal and opposite electric charges which readily separate upon application of an electric field so that charges of opposite signs are separated by a small distance (e.g., a distance of about 0.1-1 nanometers), thus providing temporary polarization (i.e., polarization present when an electric field is applied). Temporary polarization provided by the dipole layer may increase the effective dielectric constant of the high-k dielectric and may allow to use thinner high-k dielectrics and/or high-k dielectrics of suboptimal quality while maintaining transistor performance in terms of, e.g., gate leakage, carrier mobility, and subthreshold swing. In some embodiments, a thin dipole layer may directly border a channel material of choice and may be sandwiched between the channel material and the high-k dielectric. In other embodiments, a passivation layer may spontaneously form between the dipole layer and the channel material, e.g., as an oxide of the channel material. In still other embodiments, the dipole layer may be on the other side of the high-k dielectric, i.e., the high-k dielectric may be between the dipole layer and the channel material. Transistor gate stacks with dipole layers, disclosed herein, may enable the use of a wider array of transistor channel materials, while achieving desirable gate control, than realizable using conventional approaches.

In the following detailed description, various aspects of the illustrative implementations may be described using terms commonly employed by those skilled in the art to convey the substance of their work to others skilled in the art. For example, in context of source/drain (S/D) regions, the term “region” may be used interchangeably with the terms “contact” and “terminal” of a transistor. In another example, as used herein, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, analogous elements designated in the present drawings with different reference numerals after a dash, e.g., dipole layers 104-1, 104-2, and so on may be referred to together without the reference numerals after the dash, e.g., as “dipole layers 104.” In order to not clutter the drawings, if multiple instances of certain elements are illustrated, only some of the elements may be labeled with a reference sign.

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross section of a device to detect the shape and the location of various device elements described herein using, e.g., Physical Failure Analysis (PFA) would allow determination of presence of IC devices implementing transistor gate stacks with dipole layers as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices implementing transistor gate stacks with dipole layers as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

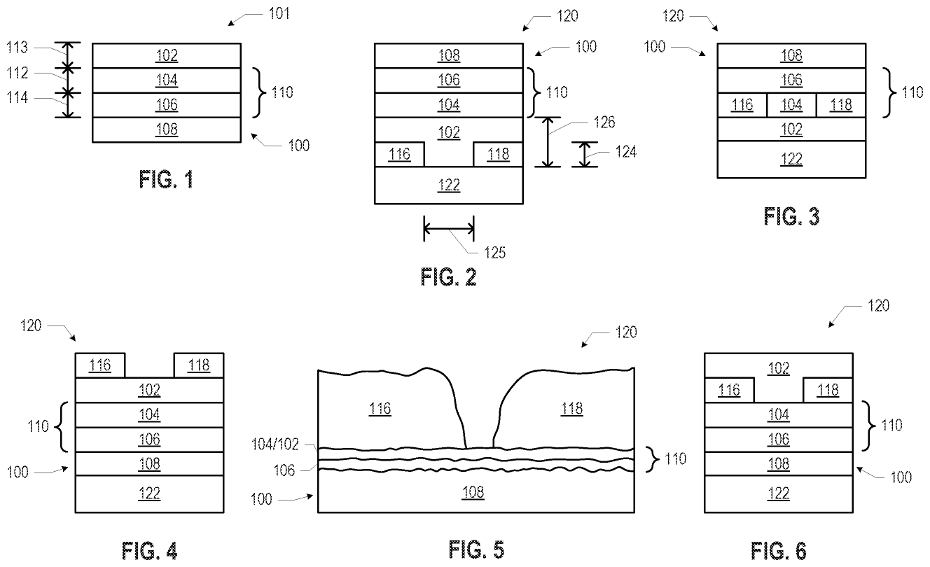

FIG. 1 is a cross-sectional side view of a transistor gate-channel arrangement 101 including a channel material 102 and a transistor gate stack 100 (also referred to as a “gate stack 100” herein), in accordance with various embodiments. The transistor gate stack 100 may include a gate electrode material 108, and a multilayer gate oxide 110 disposed between the gate electrode material 108 and the channel material 102.

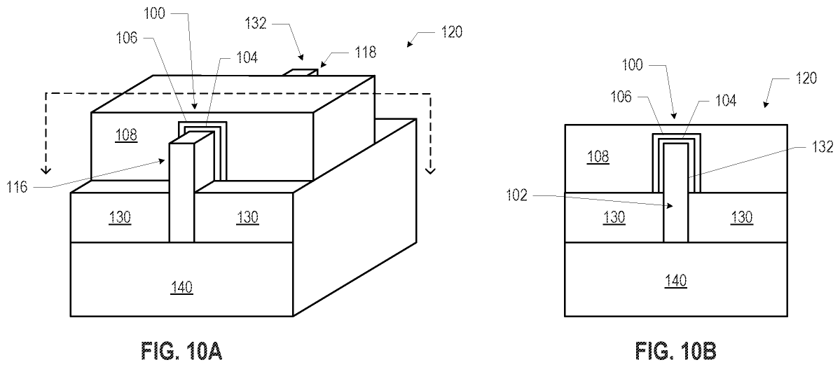

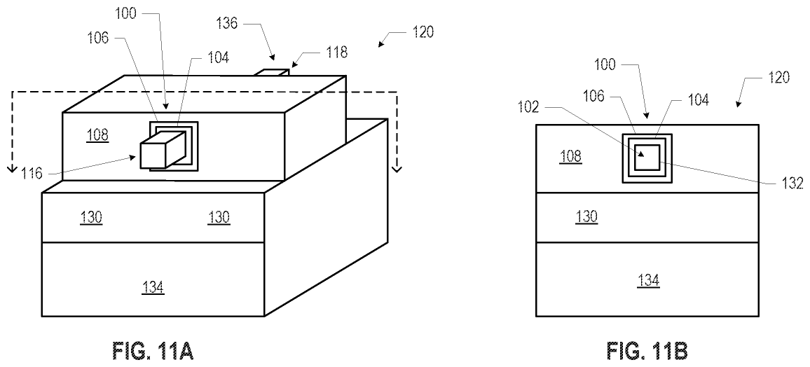

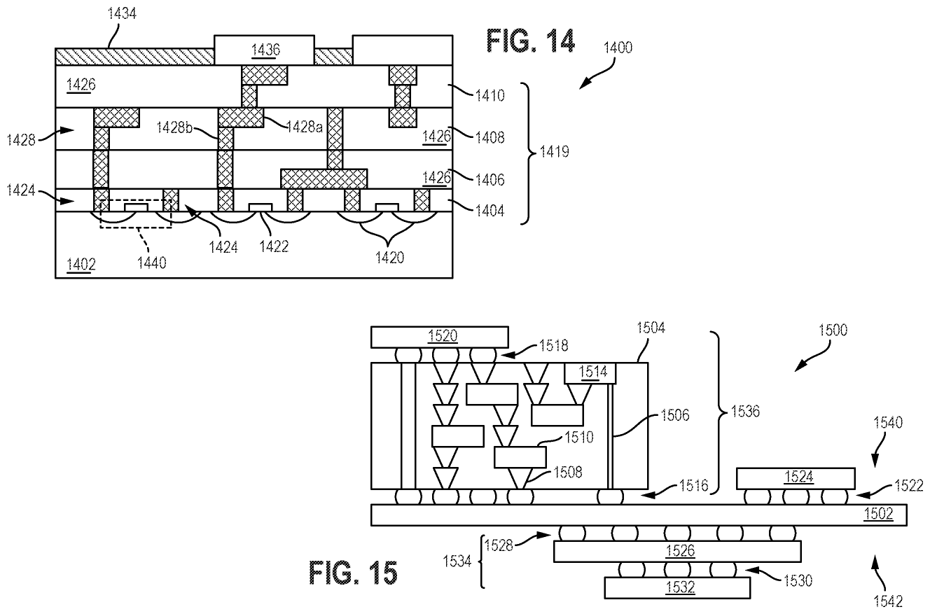

Implementations of the present disclosure may be formed or carried out on any suitable support structure, such as a substrate, a die, a wafer, or a chip. In particular, the transistor gate-channel arrangement 101 may be provided over any suitable support structure. Such a support structure is not shown in FIG. 1 but is shown, e.g., in FIGS. 2-4 and FIGS. 6-9 as a support structure 122, in FIGS. 10A and 10B as a support structure 140, in FIGS. 11A and 11B as a support structure 134, and in FIG. 14 as a support structure 1402. The support structure may, e.g., be the wafer 1300 of FIG. 13, discussed below, and may be, or be included in, a die, e.g., the singulated die 1302 of FIG. 13, discussed below. The support structure may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure may be a printed circuit board (PCB) substrate. Although a few examples of materials from which the support structure may be formed are described here, any material that may serve as a foundation upon which an IC device implementing one or more transistor gate stacks with dipole layers as described herein may be built falls within the spirit and scope of the present disclosure.

In general, the channel material 102 may be composed of semiconductor material systems including, for example, N-type or P-type materials systems. In some embodiments, the channel material 102 may include a substantially monocrystalline semiconductor, such as silicon (Si) or germanium (Ge). In some embodiments, the channel material 102 may include a compound semiconductor with a first sub-lattice of at least one element from group III of the periodic table (e.g., Al, Ga, In), and a second sub-lattice of at least one element of group V of the periodic table (e.g., P, As, Sb). In some embodiments, the channel material 102 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material 102 may include a combination of semiconductor materials.

For some example N-type transistor embodiments (i.e., for the embodiments where the transistor in which the gate stack 100 is included is an N-type metal-oxide-semiconductor (NMOS) transistor), the channel material 102 may include a III-V material having a relatively high electron mobility, such as, but not limited to InGaAs, InP, InSb, and InAs. For some such embodiments, the channel material 102 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor in which the gate stack 100 is included is a P-type metal-oxide-semiconductor (PMOS) transistor), the channel material 102 may advantageously be a group IV material having a high hole mobility, such as, but not limited to Ge or a Ge-rich SiGe alloy. For some example embodiments, the channel material 102 may have a Ge content between 0.6 and 0.9, and advantageously may be at least 0.7.

In some embodiments, the channel material 102 may be a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the channel material 102 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc.

As noted above, the channel material 102 may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors. IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

In some embodiments, the transistor in which the gate stack 100 is included may be a thin-film transistor (TFT). A TFT is a special kind of a field-effect transistor (FET) made by depositing a thin film of an active semiconductor material, as well as a dielectric layer (e.g., the multilayer gate oxide 110) and a gate electrode (e.g., the gate electrode material 108), over a support (e.g., a support structure as described above) that may be a non-conducting support. Some such materials may be deposited at relatively low temperatures, which allows depositing them within the thermal budgets imposed on back-end fabrication to avoid damaging the front end components such as the logic devices of an IC device in which the gate stack 100 may be included. At least a portion of the active semiconductor material forms a channel of the TFT. In some such embodiments, the channel material 102 may be deposited as a thin film and may include any of the oxide semiconductor materials described above.

In other embodiments, instead of being deposited at relatively low temperatures as described above with reference to the TFTs, the channel material 102 may be epitaxially grown in what typically involves relatively high-temperature processing. In such embodiments, the channel material 102 may include any of the semiconductor materials described above, including oxide semiconductor materials. In some such embodiments, the channel material 102 may be epitaxially grown directly on a semiconductor layer of a support structure over which the transistor that includes the gate stack 100 will be fabricated, in a process known as “monolithic integration.” In other such embodiments, the channel material 102 may be epitaxially grown on a semiconductor layer of another support structure and then the epitaxially grown layer of the channel material 102 may be transferred, in a process known as a “layer transfer,” to a support structure of which the transistor that includes the gate stack 100 will be fabricated, in which case the latter support structure may but does not have to include a semiconductor layer prior to the layer transfer. Layer transfer advantageously allows forming non-planar transistors, such as FinFETs or all-around gate transistors such as nanowire or nanoribbon transistors, over support structures or in layers that do not include semiconductor materials (e.g., in the back-end of an IC device). Layer transfer also advantageously allows forming transistors of any architecture (e.g., non-planar or planar transistors) without imposing the negative effects of the relatively high-temperature epitaxial growth process on devices that may already be present over a support structure.

The channel material 102 deposited at relatively low temperatures is typically a polycrystalline, polymorphous, or amorphous semiconductor, or any combination thereof. The channel material 102 epitaxially grown is typically a highly crystalline (e.g., monocrystalline or single-crystalline) material. Therefore, whether the channel material 102 is deposited at relatively low temperatures or epitaxially grown can be identified by inspecting grain size of the active portions of the channel material 102 (e.g., of the portions of the channel material 102 that form channels of transistors). An average grain size of the channel material 102 being between about 0.5 and 1 millimeters (in which case the material may be polycrystalline) or smaller than about 0.5 millimeter (in which case the material may be polymorphous or amorphous) may be indicative of the channel material 102 having been deposited (e.g., in which case the transistors in which such channel material 102 is included are TFTs). On the other hand, an average grain size of the channel material 102 being equal to or greater than about 1 millimeter (in which case the material may be a single-crystal material) may be indicative of the channel material 102 having been epitaxially grown and included in the final device either by monolithic integration or by layer transfer.

The channel material 102 may have a thickness 113. In some embodiments, the thickness 113 may be between about 5 and 75 nanometers, including all values and ranges therein, e.g., between about 5 and 50 nanometers or between about 5 and 30 nanometers.

The gate electrode material 108 may include at least one P-type work function metal or N-type work function metal, depending on whether the transistor gate stack 100 is to be included in a PMOS transistor or an NMOS transistor. For a PMOS transistor, metals that may be used for the gate electrode material 108 may include, but are not limited to, ruthenium, palladium, platinum, cobalt, nickel, and conductive metal oxides (e.g., ruthenium oxide). For an NMOS transistor, metals that may be used for the gate electrode material 108 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 108 may include a stack of two or more metal layers, where one or more metal layers are work function metal layers and at least one metal layer is a fill metal layer. Further metal layers may be included for other purposes, such as to act as a barrier layer.

The multilayer gate oxide 110 may include a high-k dielectric 106 and a dipole layer 104, arranged in the gate stack 100 so that the dipole layer 104 is disposed between the high-k dielectric 106 and the channel material 102. In some embodiments, the high-k dielectric 106 may be in contact with the gate electrode material 108. In some embodiments, the dipole layer 104 may be in contact with the channel material 102, and may provide the interface between the channel material 102 and the remainder of the multilayer gate oxide 110. In other embodiments, a passivation layer may be present between the dipole layer 104 and the channel material 102, where the dipole layer 104 may be in contact with the passivation layer and the passivation layer may be in contact with the channel material 102. Such a passivation layer may be spontaneously formed from a portion of the channel material 102 when the dipole layer 104 is provided on the channel material 102 and, therefore, is not shown in the present drawings as a separate layer (i.e., if formed, the passivation layer is a part of the channel material 102 that is closest to the interface with the dipole layer 104). In some embodiments, a passivation layer may be an oxide of the native semiconductor of the channel material 102. If the channel material 102 is a non-oxide semiconductor, then such a passivation layer may be clearly detectable in characterization images; otherwise the passivation layer may either be absent or it may be more difficult to differentiate the oxide semiconductor of the passivation layer from the oxide semiconductor of the channel material 102.

In some embodiments, the dipole layer 104 may be in contact with the high-k dielectric 106, while in other embodiments, an intermediate material may be disposed between the dipole layer 104 and the high-k dielectric 106. In some embodiments, the dipole layer 104 may include multiple regions of dipole materials having different material properties.

The dipole layer 104 may include any relatively highly polarizable material, e.g., a material with an electric flux density of at least about 10 femtocoulomb per square micrometer (fC/um²). In some embodiments, the dipole layer 104 may include any relatively highly polarizable wide bandgap material, e.g., with a bandgap of at least about 1.5 electron-volt (eV). The use of the dipole layer 104 in the multilayer gate oxide 110 may advantageously increase the effective k-value (i.e., the value of the dielectric constant, k) of the multilayer gate oxide 110 compared to the k-value of the high-k dielectric 106, while allowing to decrease the overall thickness of the multilayer gate oxide 110, and/or may allow using high-k dielectrics with suboptimal properties while reducing the negative consequences, such as gate leakage, on transistor performance.

In some embodiments, the dipole layer 104 may include oxygen and one or more rare-earth elements (e.g., the dipole layer 104 may include one or more rare-earth oxides such as yttrium oxide and/or lanthanum oxide). In some embodiments, the dipole layer 104 may be formed using a low-temperature deposition process, such as physical vapor deposition (PVD) (e.g., sputtering), atomic layer deposition (ALD), or chemical vapor deposition (CVD). The ability to deposit the dipole layer 104 at temperatures low enough to be compatible with back-end manufacturing processes represents a particular advantage. The dipole layer 104 may be deposited on sidewalls or conformably on any desired structure to a precise thickness, allowing the manufacture of transistors having any desired geometry. Additionally, deposition of the dipole layer 104 may be compatible with deposition of many materials that may act as the high-k dielectric 106 (e.g., hafnium oxide). The dipole layer 104 may have a thickness 112. In some embodiments, the thickness 112 may be below about 1.5 nanometer, e.g., below about 1 nanometer. The high-k dielectric 106 may have a thickness 114. In some embodiments, the thickness 114 may be below about 1.5 nanometer, e.g., below about 1 nanometer. In some embodiments, an overall thickness of the high-k dielectric 106 and the dipole layer 104 (i.e., a sum of the thickness 114 and the thickness 112) may be below about 2 nanometers.

The high-k dielectric 106 may include elements such as hafnium, silicon, oxygen, titanium, tantalum, lanthanum, aluminum, zirconium, barium, strontium, yttrium, lead, scandium, niobium, and zinc. Examples of high-k materials that may be used in the high-k dielectric 106 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the high-k dielectric 106 during manufacture of the gate stack 100 to improve the quality of the high-k dielectric 106. The high-k dielectric 106 may have a thickness 114. In some embodiments, the thickness 114 may be between 0.5 nanometers and 3 nanometers (e.g., between 1 and 3 nanometers, or between 1 and 2 nanometers).

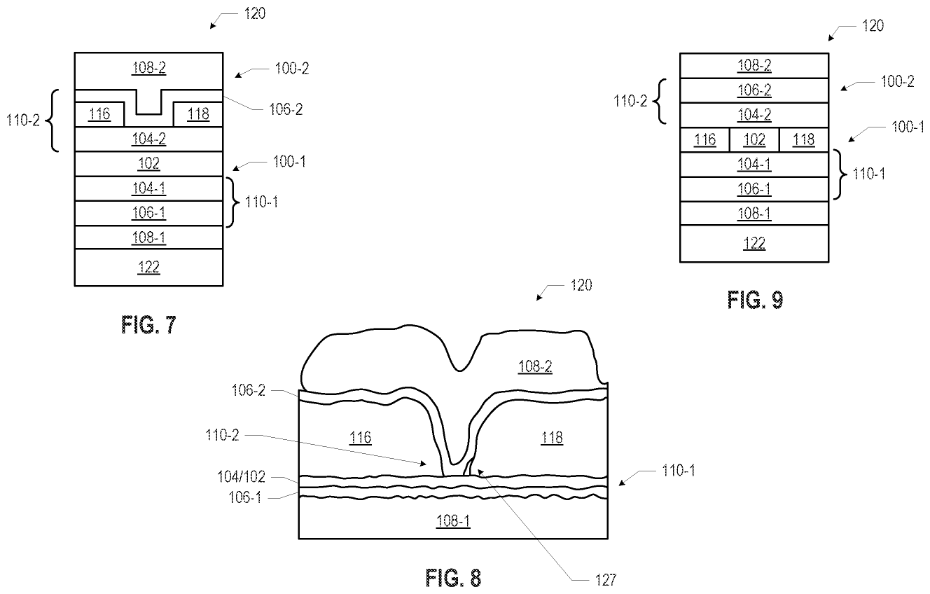

The transistor gate stack 100 may be included in any suitable transistor structure. For example, FIGS. 2-6 are cross-sectional side views of example single-gate transistors 120 including a transistor gate stack 100, FIGS. 7-9 are cross-sectional side views of example double-gate transistors 120 including a transistor gate stack 100, FIGS. 10A and 10B are perspective and cross-sectional side views, respectively, of an example FinFET 120 including a transistor gate stack, and FIGS. 11A and 11B are perspective and cross-sectional side views, respectively, of an example all-around gate transistor 120 including a transistor gate stack, in accordance with various embodiments. The transistors 120 illustrated in FIGS. 2-11 do not represent an exhaustive set of transistor structures in which a gate stack 100 may be included, but that may provide examples of such structures. Although particular arrangements of materials are discussed below with reference to FIGS. 2-11, intermediate materials may be included in the gate stacks 100 of the transistors 120 as discussed above with reference to FIG. 1. Note that FIGS. 2-6 are intended to show relative arrangements of the components therein, and that transistors 120 may include other components that are not illustrated (e.g., electrical contacts to the source region 116 and the drain region 118 to transport current in and out of the transistors 120). Any of the components of the transistors 120 discussed below with reference to FIGS. 2-11 may take the form of any of the embodiments of those components discussed above with reference to FIG. 1. Additionally, although various components of the transistors 120 are illustrated in FIGS. 2-11 as being planar rectangles or formed of rectangular solids, this is simply for ease of illustration, and embodiments of these transistors 120 may be curved, rounded, or otherwise irregularly shaped as dictated by the manufacturing processes used to fabricate the transistors 120.

FIG. 2 depicts a transistor 120 including a transistor gate stack 100 and having a single “top” gate provided by the gate electrode material 108 and the multilayer gate oxide 110 (which includes the high-k dielectric 106 and the dipole layer 104). The multilayer gate oxide 110 may be disposed between the gate electrode material 108 and the channel material 102. The multilayer gate oxide 110 may border the channel material 102; in particular, the dipole layer 104 may contact the channel material 102 without any intervening material. In the embodiment of FIG. 2, the gate stack 100 is shown as disposed on a support structure 122. The support structure 122 may be any structure on which the gate stack 100, or other elements of the transistor 120, is disposed, e.g., any of the support structures described above. In some embodiments, the support structure 122 may include a semiconductor, such as silicon. In some embodiments, the support structure 122 may include an insulating layer, such as an oxide isolation layer. For example, in the embodiments of FIGS. 2 and 3, the support structure 122 may include a semiconductor material and an interface layer dielectric (ILD) disposed between the semiconductor material and the source region 116, the channel material 102, and the drain region 118, to electrically isolate the semiconductor material of the support structure 122 from the source region 116, the channel material 102, and the drain region 118 (and thereby mitigate the likelihood that a conductive pathway will form between the source region 116 and the drain region 118 through the support structure 122). Examples of ILDs that may be included in a support structure 122 in some embodiments may include silicon oxide, silicon nitride, aluminum oxide, and/or silicon oxynitride. Any suitable ones of the embodiments of the support structure 122 described with reference to FIG. 2 may be used for the substrates 122 of others of the transistors 102 disclosed herein.

As noted above, the transistor 120 may include a source region 116 and a drain region 118 disposed on the support structure 122, with the channel material 102 disposed between the source region 116 and the drain region 118 so that at least some of the channel material 102 is coplanar with at least some of the source region 116 and the drain region 118. The source region 116 and the drain region 118 may have a thickness 124, and the channel material 102 may have a thickness 126. The thickness 126 may take the form of any of the embodiments of the thickness 113 discussed above with reference to FIG. 1. In some embodiments, the thickness 124 may be less than the thickness 126 (as illustrated in FIG. 2, with the source region 116 and the drain region 118 each disposed between some of the channel material 102 and the support structure 122), while in other embodiments, the thickness 124 may be equal to the thickness 126. In some embodiments, the channel material 102, the dipole layer 104, the high-k dielectric 106, and/or the gate electrode material 108 may conform around the source region 116 and/or the drain region 118. The source region 116 and the drain region 118 may be spaced apart by a distance 125 that is the gate length of the transistor 120. In some embodiments, the gate length may be between 10 and 30 nanometers (e.g., between 12 and 20 nanometers, or approximately 25 nanometers).

The source region 116 and the drain region 118 may be formed using any suitable processes known in the art. For example, the source region 116 and the drain region 118 may generally be formed using either an implantation/diffusion process or an etching/deposition process. In the former process, dopants such as boron, aluminum, antimony, phosphorous, or arsenic may be ion-implanted into the channel material to form the source region 116 and the drain region 118. An annealing process that activates the dopants and causes them to diffuse further into the channel material 102 typically follows the ion implantation process. In the latter process, the channel material 102 may first be etched to form recesses at the locations of the source region 116 and the drain region 118. An epitaxial deposition process may then be carried out to fill the recesses with material that is used to fabricate the source region 116 and the drain region 118. In some implementations, the source region 116 and the drain region 118 may be fabricated using a silicon alloy such as silicon germanium or silicon carbide. In some implementations, the epitaxially deposited silicon alloy may be doped in situ with dopants such as boron, arsenic, or phosphorous. In further embodiments, the source region 116 and the drain region 118 may be formed using one or more alternate semiconductor materials such as germanium or a group III-V material or alloy. And in further embodiments, one or more layers of metal and/or metal alloys may be used to form the source region 116 and the drain region 118. Any suitable ones of the embodiments of the source region 116 and the drain region 118 described above may be used for any of the source regions 116 and drain regions 118 described herein.

FIG. 3 depicts a transistor 120 including a transistor gate stack 100 and having a single “top” gate provided by the gate electrode material 108 and the multilayer gate oxide 110 (which includes the high-k dielectric 106 and the dipole layer 104). The multilayer gate oxide 110 may be disposed between the gate electrode material 108 and the channel material 102. The multilayer gate oxide 110 may border the channel material 102; in particular, the dipole layer 104 may contact the channel material 102 without any intervening material. In the embodiment of FIG. 3, the gate stack 100 is shown as disposed on a support structure 122. The transistor 120 may include a source region 116 and a drain region 118 disposed on the support structure 122, with the dipole layer 104 disposed between the source region 116 and the drain region 118 so that at least some of the dipole layer 104 is coplanar with at least some of the source region 116 and the drain region 118. As discussed above, in some embodiments, the support structure 122 of FIG. 3 may include a semiconductor material and ILD disposed between the semiconductor material and the source region 116, the channel material 102, and the drain region 118, to electrically isolate the semiconductor material of the support structure 122 from the source region 116, the channel material 102, and the drain region 118. In some embodiments, the dipole layer 104, the high-k dielectric 106, and/or the gate electrode material 108 may conform around the source region 116 and/or the drain region 118.

FIG. 4 depicts a transistor 120 including a transistor gate stack 100 and having a single “bottom” gate provided by the gate electrode material 108 and the multilayer gate oxide 110 (which includes the high-k dielectric 106 and the dipole layer 104). The multilayer gate oxide 110 may be disposed between the gate electrode material 108 and the channel material 102. The multilayer gate oxide 110 may border the channel material 102; in particular, the dipole layer 104 may contact the channel material 102 without any intervening material. In the embodiment of FIG. 4, the gate stack 100 is shown as disposed on a support structure 122 in an orientation “upside down” to the one illustrated in FIG. 2; that is, the gate electrode material 108 may be disposed between the support structure 122 and the channel material 102. The transistor 120 may include a source region 116 and a drain region 118 disposed on the channel material 102 such that the source region 116 and the drain region 118 are not coplanar with the channel material 102.

FIG. 5 depicts a transistor 120 having the structure of the transistor 120 of FIG. 4. In particular, the transistor 120 of FIG. 5 includes a transistor gate stack 100 and has a single “bottom” gate provided by the gate electrode material 108 and the multilayer gate oxide 110 (which includes the high-k dielectric 106 and the dipole layer 104). In the embodiment of FIG. 5, the dipole layer 104 provides the channel material 102, so the channel material 102 is not separately labeled. The transistor 120 of FIG. 5 may also include a support structure 122 (not shown) arranged so that the gate electrode material 108 is disposed between the support structure 122 and the multilayer gate oxide 110. The transistor 120 may include a source region 116 and a drain region 118 disposed on the channel 102 such that the source region 116 and the drain region 118 are not coplanar with the channel material 102. In the embodiment depicted in FIG. 5, the source region 116 and the drain region 118 may be deposited on the dipole layer 104. Any suitable materials may be used to form the transistor 120 of FIG. 5, as discussed above. For example, the gate electrode material 108 may be titanium nitride, the high-k dielectric 106 may be hafnium oxide, and the source region 116 and the drain region 118 may be formed of aluminum. The gate length of the transistor 120 of FIG. 5 may be in the ranges described above, e.g., approximately 12-25 nanometers.

FIG. 6 depicts a transistor 120 including a transistor gate stack 100 and having a single “bottom” gate provided by the gate electrode material 108 and the multilayer gate oxide 110 (which includes the high-k dielectric 106 and the dipole layer 104). The multilayer gate oxide 110 may be disposed between the gate electrode material 108 and the channel material 102. The multilayer gate oxide 110 may border the channel material 102; in particular, the dipole layer 104 may contact the channel material 102 without any intervening material. In the embodiment of FIG. 6, the gate stack 100 is shown as disposed on a support structure 122 in an orientation “upside down” to the one illustrated in FIG. 2; that is, the gate electrode material 108 may be disposed between the support structure 122 and the channel material 102. The transistor 120 may include a source region 116 and a drain region 118 disposed on the channel material 102 such that at least some of the source region 116 and at least some of the drain region 118 are coplanar with at least some of the channel material 102. In some embodiments, the source region 116 and the drain region 118 may each be disposed between some of the channel material 102 and the support structure 122, as illustrated in FIG. 6, while in other embodiments, the channel material 102 may not extend “above” the source region 116 or the drain region 118. In some embodiments, the channel material 102 may conform around the source region 116 and/or the drain region 118.

FIG. 7 depicts a double-gate transistor 120 including two transistor gate stacks 100-1 and 100-2 and having “bottom” and “top” gates provided by the gate electrode material 108-1/multilayer gate oxide 110-1 and the gate electrode material 108-2/multilayer gate oxide 110-2, respectively. The multilayer gate oxides 110-1 and 110-2 may include a high-k dielectric 106-1 and 106-2, and dipole layer 104-1 and 104-2, respectively. Each multilayer gate oxide 110 may be disposed between the corresponding gate electrode material 108 and the channel material 102. Each multilayer gate oxide 110 may border the channel material 102; in particular, the dipole layer 104-1 and 104-2 may contact the channel material 102 without any intervening material (and in some embodiments, the dipole layer 104-1/104-2 may be the channel material 102). The transistor 120 may include a source region 116 and a drain region 118 disposed proximate to the channel material 102. In the embodiment illustrated in FIG. 7, the source region 116 and the drain region 118 are disposed on the dipole layer 104-2, and the high-k dielectric 106-2 is disposed conformably around the source region 116, the dipole layer 104-2, and the drain region 118. The gate electrode material 108-2 is disposed on the high-k dielectric 106-2. In the embodiment of FIG. 7, at least some of the source region 116 and at least some of the drain region 118 are coplanar with at least some of the high-k dielectric 106-2.

FIG. 8 depicts a double-gate transistor 120 having the structure of the transistor 120 of FIG. 7. In particular, the transistor 120 of FIG. 8 includes two transistor gate stacks 100-1 and 100-2 and having “bottom” and “top” gates provided by the gate electrode material 108-1/multilayer gate oxide 110-1 and the gate electrode material 108-2/multilayer gate oxide 110-2, respectively. In the embodiment of FIG. 8, a continuous region provides the dipole layer 104-1, the channel material 102, and the dipole layer 104-2. The transistor 120 of FIG. 8 may also include a support structure 122 (not shown) arranged so that the gate electrode material 108-1 is disposed between the support structure 122 and the multilayer gate oxide 110. The transistor 120 may include a source region 116 and a drain region 118 disposed on the channel material 102 such that the source region 116 and the drain region 118 are not coplanar with the channel material 102. In the embodiment depicted in FIG. 8, the source region 116 and the drain region 118 may be deposited on the dipole layer 104. During manufacture, a void 127 may be formed between the high-k dielectric 106-2 and the dipole layer 104; while such voids 127 may reduce the performance of the transistor 120, the transistor 120 may still function adequately as long as adequate coupling between the high-k dielectric 106-2 and the dipole layer 104 is achieved. Any suitable materials may be used to form the transistor 120 of FIG. 8, as discussed above. For example, the gate electrode material 108-1 may be titanium nitride, the high-k dielectrics 106-1 and 106-2 may be hafnium oxide, the source region 116 and the drain region 118 may be formed of aluminum, and the gate electrode material 108-2 may be palladium. The gate length of the transistor 120 of FIG. 8 may be in the ranges described above, e.g., approximately 12-25 nanometers.

FIG. 9 depicts a double-gate transistor 120 including two transistor gate stacks 100-1 and 100-2 and having “bottom” and “top” gates provided by the gate electrode material 108-1/multilayer gate oxide 110-1 and the gate electrode material 108-2/multilayer gate oxide 110-2, respectively. Each multilayer gate oxide 110 may include a high-k dielectric 106 and a dipole layer 104. Each multilayer gate oxide 110 may be disposed between the corresponding gate electrode material 108 and the channel material 102. Each multilayer gate oxide 110 may border the channel material 102; in particular, the dipole layer 104-1 and 104-2 may contact the channel material 102 without any intervening material. The transistor 120 may include a source region 116 and a drain region 118 disposed proximate to the channel material 102. In the embodiment illustrated in FIG. 9, the source region 116 and the drain region 118 are coplanar with the channel material 102, and disposed between the high-k dielectrics 106-1 and 106-2. The relative arrangement of the source region 116, the drain region 118, and the channel material 102 may take the form of any of the embodiments discussed above with reference to FIG. 2.

FIGS. 10A and 10B are perspective and cross-sectional side views, respectively, of an example FinFET 120 including a transistor gate stack 100, in accordance with various embodiments. The transistor 120 of FIGS. 10A and 10B may include a channel material 102, and a gate stack 100 including a gate electrode material 108, a high-k dielectric 106 and a dipole layer 104. The dipole layer 104 may be disposed between the high-k dielectric 106 and the channel material 102 (e.g., the dipole layer 104 may be in contact with the channel material 102). In the FinFET 120 illustrated in FIGS. 10A and 10B, a fin 132 formed of a semiconductor material may extend from a base 140 of the semiconductor material. An insulator material 130, e.g., an oxide material, typically referred to as a “shallow trench insulator” (STI), may be disposed on either side of the fin 132. In some embodiments, the insulator material 130 may include any of the materials discussed herein with reference to the high-k dielectric 106.

The gate stack 100 may wrap around the fin 132 as shown, with the channel material 102 corresponding to the portion of the fin 132 wrapped by the gate stack 100. In particular, the dipole layer 104 may wrap around the channel material 102 of the fin 132, the high-k dielectric 106 may wrap around the dipole layer 104, and the gate electrode material 108 may wrap around the high-k dielectric 106. The fin 132 may include a source region 116 and a drain region 118 on either side of the gate stack 100, as shown. The composition of the channel material 102, the source region 116, and a drain region 118 may take the form of any of the embodiments disclosed herein, or known in the art. Although the fin 132 illustrated in FIGS. 10A and 10B is shown as having a rectangular cross section, the fin 132 may instead have a cross section that is rounded or sloped at the “top” of the fin 132, and the gate stack 100 may conform to this rounded or sloped fin 132. In use, the FinFET 120 may form conducting channels on three “sides” of the fin 132, potentially improving performance relative to single-gate transistors (which may form conducting channels on one “side” of the channel material 102) and double-gate transistors (which may form conducting channels on two “sides” of the channel material 102).

FIGS. 11A and 11B are perspective and cross-sectional side views, respectively, of an example all-around gate transistor 120 including a transistor gate stack 100, in accordance with various embodiments. The transistor 120 of FIGS. 11A and 11B may include a channel material 102, and a gate stack 100 including a gate electrode material 108, a high-k dielectric 106 and IGZO 104. The dipole layer 104 may be disposed between the high-k dielectric 106 and the channel material 102 (e.g., the dipole layer 104 may be in contact with the channel material 102). In the all-around gate transistor 120 illustrated in FIGS. 11A and 11B, an elongated structure 136 formed of a semiconductor material may extend above a support structure 134 and a layer of insulator material 130. The elongated structure 136 may take the form of a nanowire or nanoribbon, for example. The gate stack 100 may wrap entirely or almost entirely around the elongated structure 136, as shown, with the channel material 102 corresponding to the portion of the elongated structure 136 wrapped by the gate stack 100. In particular, the dipole layer 104 may wrap around the channel material 102 of the fin 132, the high-k dielectric 106 may wrap around the dipole layer 104, and the gate electrode material 108 may wrap around the high-k dielectric 106. In some embodiments, the gate stack 100 may fully encircle the elongated structure 136. The elongated structure 136 may include a source region 116 and a drain region 118 on either side of the gate stack 100, as shown. The composition of the channel material 102, the source region 116, and a drain region 118 may take the form of any of the embodiments disclosed herein, or known in the art. Although the elongated structure 136 illustrated in FIGS. 11A and 11B is shown as having a substantially square cross section, the elongated structure 136 may instead have a cross section that is rounded or otherwise irregularly shaped, and the gate stack 100 may conform to the shape of the elongated structure 136. In the embodiments where the cross section of the elongated structure 136 is substantially square or circular, a transistor in which the elongated structure 136 is used to provide a channel may be referred to as a “nanowire” transistor. Furthermore, in some embodiments, instead of being substantially square, the cross section of the elongated structure 136 of the FinFET 120 may be substantially rectangular (again, such a substantially rectangular cross section may be rounded or otherwise irregularly shaped), in which case a transistor in which the elongated structure 136 is used to provide a channel may be referred to as a “nanoribbon” transistor. Still further, in some embodiments, the cross section of the elongated structure 136 of the FinFET 120 may be such that the width of the elongated structure 136 (a dimension measured substantially parallel to a plane of the insulator material 130 and a plane of the support structure 134 and substantially perpendicular to the longitudinal axis of the elongated structure 136) may be several times greater than the thickness of the elongated structure 136 (a dimension measured substantially perpendicular to a plane of the insulator material 130 and a plane of the support structure 134), in which case a transistor in which the elongated structure 136 is used to provide a channel may be referred to as a “nanosheet” transistor. In use, the FinFET 120 may form conducting channels on more than three “sides” of the elongated structure 136, potentially improving performance relative to FinFETs. Although FIGS. 11A and 11B depict an embodiment in which the longitudinal axis of the elongated structure 136 runs substantially parallel to a plane of the insulator material 130 (and a plane of the support structure 134), this need not be the case; in other embodiments, for example, the elongated structure 136 may be oriented “vertically” so as to be perpendicular to a plane of the oxide 130 (or plane of the support structure 134).

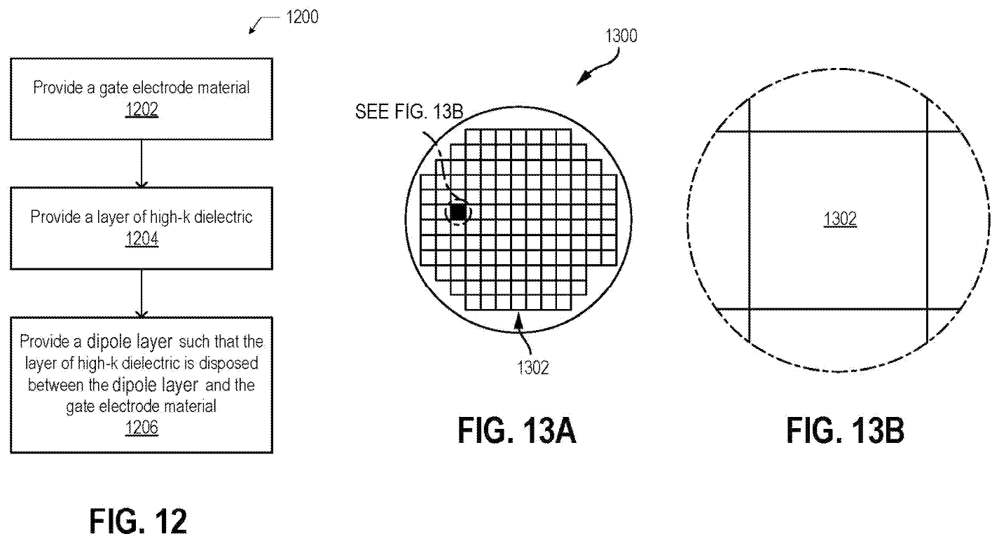

The transistor gate stacks 100 disclosed herein may be manufactured using any suitable techniques. For example, FIG. 12 is a flow diagram of an example method 1200 of manufacturing a transistor gate stack, in accordance with various embodiments. Although the operations of the method 1200 are illustrated once each and in a particular order, the operations may be performed in any suitable order and repeated as desired. For example, one or more operations may be performed in parallel to manufacture multiple transistor gate stacks substantially simultaneously. In another example, the operations may be performed in a different order to reflect the structure of a transistor in which the transistor gate stack will be included (e.g., the gate electrode material of the transistor 120 of FIG. 5 may be provided before the dipole layer 104, while the gate electrode material of the transistor 120 of FIG. 10 may be provided after the dipole layer 104).

At 1202, a gate electrode material may be provided. The gate electrode material provided at 1202 may take the form of any of the embodiments of the gate electrode material 108 disclosed herein, for example (e.g., any of the embodiments discussed herein with reference to a transistor 120). The gate electrode material may be provided at 1202 using any suitable deposition and patterning technique known in the art.

At 1204, a layer of high-k dielectric may be provided. The high-k dielectric provided at 1204 may take the form of any of the embodiments of the high-k dielectric 106 disclosed herein, for example. In some embodiments, the layer of high-k dielectric may be provided at 1204 so as to be in contact with the gate electrode material of 1202. In other embodiments, an intermediate material may be disposed between the gate electrode material and the layer of high-k dielectric. The high-k dielectric may be provided at 1204 using any suitable technique known in the art.

At 1206, a dipole layer may be provided such that the layer of high-k dielectric is disposed between the dipole layer and the gate electrode material. The dipole layer provided at 1206 may take the form of any of the embodiments of the dipole layer 104 disclosed herein. In some embodiments, the dipole layer provided at 1206 may be in contact with a channel material of a transistor (e.g., the channel material 102 of any of the transistors 120 disclosed herein). The dipole layer may be provided at 1206 using any suitable technique known in the art. For example, in some embodiments, the dipole layer may be provided by PVD, such as sputtering. In some embodiments, the dipole layer may be provided by ALD. In some embodiments, the dipole layer may be provided by CVD.

The method 1200 may further include other manufacturing operations related to fabrication of other components of a transistor 120. For example, the method 1200 may include providing a channel material over the dipole layer provided at 1206 (e.g., in accordance with any suitable ones of the embodiments discussed above). In some embodiments, the method 1200 may include providing a source region and a drain region (e.g., in accordance with any suitable ones of the embodiments discussed above).

The transistor gate stacks with dipole layers disclosed herein may be included in any suitable electronic device. FIGS. 13-16 illustrate various examples of apparatuses that may include one or more of the transistor gate stacks with dipole layers disclosed herein.

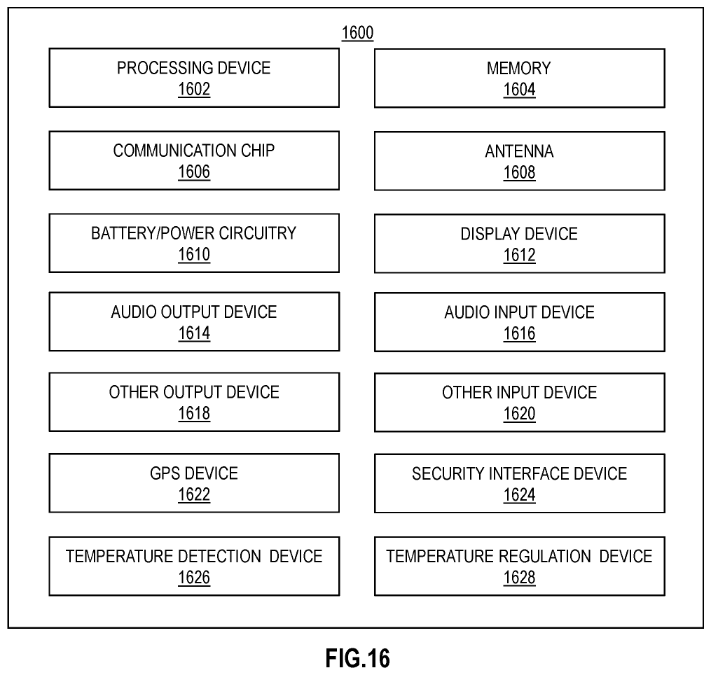

FIGS. 13A and 13B are top views of a wafer 1300 and dies 1302 that may include one or more transistor gate stacks with dipole layers in accordance with any of the embodiments disclosed herein. The wafer 1300 may be composed of semiconductor material and may include one or more dies 1302 having IC structures formed on a surface of the wafer 1300. Each of the dies 1302 may be a repeating unit of a semiconductor product that includes any suitable IC (e.g., ICs including one or more transistors 120 that include one or more gate stacks 100). After the fabrication of the semiconductor product is complete (e.g., after manufacture of a gate stack 100 in a transistor 120), the wafer 1300 may undergo a singulation process in which each of the dies 1302 is separated from one another to provide discrete “chips” of the semiconductor product. In particular, devices that include a transistor gate stack as disclosed herein may take the form of the wafer 1300 (e.g., not singulated) or the form of the die 1302 (e.g., singulated). The die 1302 may include one or more transistors (e.g., one or more of the transistors 1440 of FIG. 14, discussed below, which may take the form of any of the transistors 120) and/or supporting circuitry to route electrical signals to the transistors, as well as any other IC components. In some embodiments, the wafer 1300 or the die 1302 may include a memory device (e.g., a static random-access memory (SRAM) device), a logic device (e.g., an AND, OR, NAND, or NOR gate), or any other suitable circuit element. Multiple ones of these devices may be combined on a single die 1302. For example, a memory array formed by multiple memory devices may be formed on a same die 1302 as a processing device (e.g., the processing device 1602 of FIG. 16) or other logic that is configured to store information in the memory devices or execute instructions stored in the memory array.

FIG. 14 is a cross-sectional side view of an IC device 1400 that may include one or more transistor gate stacks with dipole layers in accordance with any of the embodiments disclosed herein. The IC device 1400 may be formed on a support structure 1402 (e.g., the wafer 1300 of FIG. 13A) and may be included in a die (e.g., the die 1302 of FIG. 13B). The support structure 1402 may be a semiconductor substrate composed of semiconductor material systems including, for example, N-type or P-type materials systems. The support structure 1402 may include, for example, a crystalline substrate formed using a bulk silicon or a SOI substructure. In some embodiments, the semiconductor support structure 1402 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the support structure 1402. Although a few examples of materials from which the support structure 1402 may be formed are described here, any material that may serve as a foundation for an IC device 1400 may be used. The support structure 1402 may be part of a singulated die (e.g., the dies 1302 of FIG. 13B) or a wafer (e.g., the wafer 1300 of FIG. 13A).

The IC device 1400 may include one or more device layers 1404 disposed on the support structure 1402. The device layer 1404 may include features of one or more transistors 1440 (e.g., metal-oxide-semiconductor field-effect transistors (MOSFETs)) formed on the support structure 1402. The device layer 1404 may include, for example, one or more source and/or drain (S/D) regions 1420, a gate 1422 to control current flow in the transistors 1440 between the S/D regions 1420, and one or more S/D contacts 1424 to route electrical signals to/from the S/D regions 1420. The transistors 1440 may include additional features not depicted for the sake of clarity, such as device isolation regions, gate contacts, and the like. The transistors 1440 are not limited to the type and configuration depicted in FIG. 14 and may include a wide variety of other types and configurations such as, for example, planar transistors, non-planar transistors, or a combination of both. Non-planar transistors may include FinFET transistors, such as double-gate transistors or FinFETs (e.g., as described with reference to FIGS. 10A and 10B), and wrap-around or all-around gate transistors, such as nanoribbon and nanowire transistors (e.g., as described with reference to FIGS. 11A and 11B). In particular, one or more of the transistors 1440 may include one or more transistor gate stacks 100 in accordance with any of the embodiments disclosed herein. For example, a transistor 1440 may take the form of any of the transistors 120 disclosed herein (e.g., any of the single-gate transistors discussed herein with reference to FIGS. 2-6, any of the double-gate transistors discussed herein with reference to FIGS. 7-9, any of the FinFETs discussed herein with reference to FIGS. 10A and 10B, and any of the all-around-gate transistors discussed herein with reference to FIGS. 11A and 11B). The S/D regions 1420 may include the source region 116 and the drain region 118. Thin-film transistors 120 including the gate stack 100 may be particularly advantageous when used in the metal layers of a microprocessor device for analog circuitry, logic circuitry, or memory circuitry, and may be formed along with existing complementary metal-oxide-semiconductor (CMOS) processes.

Each transistor 1440 may include a gate 1422 formed of at least two layers, a gate dielectric layer and a gate electrode layer. The gate electrode layer may take the form of any of the embodiments of the gate electrode material 108 disclosed herein. In embodiments in which a transistor 1440 includes one or more transistor gate stacks 100, the gate dielectric layer may take the form of any of the embodiments of the multilayer gate oxide 110 disclosed herein, and may include IGZO 104 and a high-k dielectric 106. Generally, the gate dielectric layer of a transistor 1440 may include one layer or a stack of layers, and the one or more layers may include silicon oxide, silicon dioxide, and/or a high-k dielectric material. The high-k dielectric material included in the gate dielectric layer of the transistor 1440 may take the form of any of the embodiments of the high-k dielectric 106 disclosed herein, for example.

In some embodiments, when viewed as a cross section of the transistor 1440 along the source-channel-drain direction, the gate electrode may consist of a U-shaped structure that includes a bottom portion substantially parallel to the surface of the substrate and two sidewall portions that are substantially perpendicular to the top surface of the substrate (e.g., as discussed above with reference to the FinFET 120 of FIGS. 10A and 10B). In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers. In some embodiments, the gate electrode may consist of a V-shaped structure (e.g., when the fin 132 does not have a “flat” upper surface, but instead has a rounded peak).

In some embodiments, a pair of sidewall spacers may be formed on opposing sides of the gate stack to bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1420 may be formed within the support structure 1402 adjacent to the gate 1422 of each transistor 1440. The S/D regions 1420 may take the form of any of the embodiments of the source region 116 and the drain region 118 discussed above with reference to the transistors 120. In other embodiments, the S/D regions 1420 may be formed using any suitable processes known in the art. For example, the S/D regions 1420 may be formed using either an implantation/diffusion process or a deposition process. In the former process, dopants such as boron, aluminum, antimony, phosphorous, or arsenic may be ion-implanted into the support structure 1402 to form the S/D regions 1420. An annealing process that activates the dopants and causes them to diffuse farther into the support structure 1402 may follow the ion implantation process. In the latter process, an epitaxial deposition process may provide material that is used to fabricate the S/D regions 1420. In some implementations, the S/D regions 1420 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1420 may be formed using one or more alternate semiconductor materials such as germanium or a group III-V material or alloy. In further embodiments, one or more layers of metal and/or metal alloys may be used to form the S/D regions 1420 (e.g., as discussed above with reference to the source region 116 and the drain region 118). In some embodiments, an etch process may be performed before the epitaxial deposition to create recesses in the support structure 1402 in which the material for the S/D regions 1420 is deposited.

Electrical signals, such as power and/or input/output (I/O) signals, may be routed to and/or from the transistors 1440 of the device layer 1404 through one or more interconnect layers disposed on the device layer 1404 (illustrated in FIG. 14 as interconnect layers 1406-1410). For example, electrically conductive features of the device layer 1404 (e.g., the gate 1422 and the S/D contacts 1424) may be electrically coupled with the interconnect structures 1428 of the interconnect layers 1406-1410. The one or more interconnect layers 1406-1410 may form an interlayer dielectric (ILD) stack 1419 of the IC device 1400.

The interconnect structures 1428 may be arranged within the interconnect layers 1406-1410 to route electrical signals according to a wide variety of designs (in particular, the arrangement is not limited to the particular configuration of interconnect structures 1428 depicted in FIG. 14). Although a particular number of interconnect layers 1406-1410 is depicted in FIG. 14, embodiments of the present disclosure include IC devices having more or fewer interconnect layers than depicted.

In some embodiments, the interconnect structures 1428 may include trench structures 1428a (sometimes referred to as “lines”) and/or via structures 1428b (sometimes referred to as “holes”) filled with an electrically conductive material such as a metal. The trench structures 1428a may be arranged to route electrical signals in a direction of a plane that is substantially parallel with a surface of the support structure 1402 upon which the device layer 1404 is formed. For example, the trench structures 1428a may route electrical signals in a direction in and out of the page from the perspective of FIG. 14. The via structures 1428b may be arranged to route electrical signals in a direction of a plane that is substantially perpendicular to the surface of the support structure 1402 upon which the device layer 1404 is formed. In some embodiments, the via structures 1428b may electrically couple trench structures 1428a of different interconnect layers 1406-1410 together.

The interconnect layers 1406-1410 may include a dielectric material 1426 disposed between the interconnect structures 1428, as shown in FIG. 14. In some embodiments, the dielectric material 1426 disposed between the interconnect structures 1428 in different ones of the interconnect layers 1406-1410 may have different compositions; in other embodiments, the composition of the dielectric material 1426 between different interconnect layers 1406-1410 may be the same.

A first interconnect layer 1406 (referred to as Metal 1 or “M1”) may be formed directly on the device layer 1404. In some embodiments, the first interconnect layer 1406 may include trench structures 1428a and/or via structures 1428b, as shown. The trench structures 1428a of the first interconnect layer 1406 may be coupled with contacts (e.g., the S/D contacts 1424) of the device layer 1404.

A second interconnect layer 1408 (referred to as Metal 2 or “M2”) may be formed directly on the first interconnect layer 1406. In some embodiments, the second interconnect layer 1408 may include via structures 1428b to couple the trench structures 1428a of the second interconnect layer 1408 with the trench structures 1428a of the first interconnect layer 1406. Although the trench structures 1428a and the via structures 1428b are structurally delineated with a line within each interconnect layer (e.g., within the second interconnect layer 1408) for the sake of clarity, the trench structures 1428a and the via structures 1428b may be structurally and/or materially contiguous (e.g., simultaneously filled during a dual-damascene process) in some embodiments.

A third interconnect layer 1410 (referred to as Metal 3 or “M3”) (and additional interconnect layers, as desired) may be formed in succession on the second interconnect layer 1408 according to similar techniques and configurations described in connection with the second interconnect layer 1408 or the first interconnect layer 1406.

The IC device 1400 may include a solder resist material 1434 (e.g., polyimide or similar material) and one or more bond pads 1436 formed on the interconnect layers 1406-1410. The bond pads 1436 may be electrically coupled with the interconnect structures 1428 and configured to route the electrical signals of the transistor(s) 1440 to other external devices. For example, solder bonds may be formed on the one or more bond pads 1436 to mechanically and/or electrically couple a chip including the IC device 1400 with another component (e.g., a circuit board). The IC device 1400 may have other alternative configurations to route the electrical signals from the interconnect layers 1406-1410 than depicted in other embodiments. For example, the bond pads 1436 may be replaced by or may further include other analogous features (e.g., posts) that route the electrical signals to external components.

FIG. 15 is a cross-sectional side view of an IC device assembly 1500 that may include components having one or more transistor gate stacks with dipole layers in accordance with any of the embodiments disclosed herein. The IC device assembly 1500 includes a number of components disposed on a circuit board 1502 (which may be, e.g., a motherboard). The IC device assembly 1500 includes components disposed on a first face 1540 of the circuit board 1502 and an opposing second face 1542 of the circuit board 1502; generally, components may be disposed on one or both faces 1540 and 1542. In particular, any suitable ones of the components of the IC device assembly 1500 may include any of the transistor gate stacks 100 disclosed herein (e.g., in any of the transistors 120 disclosed herein).

In some embodiments, the circuit board 1502 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1502. In other embodiments, the circuit board 1502 may be a non-PCB substrate.

The IC device assembly 1500 illustrated in FIG. 15 includes a package-on-interposer structure 1536 coupled to the first face 1540 of the circuit board 1502 by coupling components 1516. The coupling components 1516 may electrically and mechanically couple the package-on-interposer structure 1536 to the circuit board 1502, and may include solder balls (as shown in FIG. 15), male and female portions of a socket, an adhesive, an underfill material, and/or any other suitable electrical and/or mechanical coupling structure.

The package-on-interposer structure 1536 may include an IC package 1520 coupled to an interposer 1504 by coupling components 1518. The coupling components 1518 may take any suitable form for the application, such as the forms discussed above with reference to the coupling components 1516. Although a single IC package 1520 is shown in FIG. 15, multiple IC packages may be coupled to the interposer 1504; indeed, additional interposers may be coupled to the interposer 1504. The interposer 1504 may provide an intervening substrate used to bridge the circuit board 1502 and the IC package 1520. The IC package 1520 may be or include, for example, a die (the die 1302 of FIG. 13B), an IC device (e.g., the IC device 1400 of FIG. 14), or any other suitable component. Generally, the interposer 1504 may spread a connection to a wider pitch or reroute a connection to a different connection. For example, the interposer 1504 may couple the IC package 1520 (e.g., a die) to a ball grid array (BGA) of the coupling components 1516 for coupling to the circuit board 1502. In the embodiment illustrated in FIG. 15, the IC package 1520 and the circuit board 1502 are attached to opposing sides of the interposer 1504; in other embodiments, the IC package 1520 and the circuit board 1502 may be attached to a same side of the interposer 1504. In some embodiments, three or more components may be interconnected by way of the interposer 1504.

The interposer 1504 may be formed of an epoxy resin, a fiberglass-reinforced epoxy resin, a ceramic material, or a polymer material such as polyimide. In some implementations, the interposer 1504 may be formed of alternate rigid or flexible materials that may include the same materials described above for use in a semiconductor substrate, such as silicon, germanium, and other group III-V and group IV materials. The interposer 1504 may include metal interconnects 1508 and vias 1510, including but not limited to through-silicon vias (TSVs) 1506. The interposer 1504 may further include embedded devices 1514, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1504. The package-on-interposer structure 1536 may take the form of any of the package-on-interposer structures known in the art.

The IC device assembly 1500 may include an IC package 1524 coupled to the first face 1540 of the circuit board 1502 by coupling components 1522. The coupling components 1522 may take the form of any of the embodiments discussed above with reference to the coupling components 1516, and the IC package 1524 may take the form of any of the embodiments discussed above with reference to the IC package 1520.

The IC device assembly 1500 illustrated in FIG. 15 includes a package-on-package structure 1534 coupled to the second face 1542 of the circuit board 1502 by coupling components 1528. The package-on-package structure 1534 may include an IC package 1526 and an IC package 1532 coupled together by coupling components 1530 such that the IC package 1526 is disposed between the circuit board 1502 and the IC package 1532. The coupling components 1528 and 1530 may take the form of any of the embodiments of the coupling components 1516 discussed above, and the IC packages 1526 and 1532 may take the form of any of the embodiments of the IC package 1520 discussed above. The package-on-package structure 1534 may be configured in accordance with any of the package-on-package structures known in the art.

FIG. 16 is a block diagram of an example computing device 1600 that may include one or more components including one or more transistor gate stacks with dipole layers in accordance with any of the embodiments disclosed herein. For example, any suitable ones of the components of the computing device 1600 may include a die (e.g., the die 1302 (FIG. 13B)) having one or more transistors 120 including one or more transistor gate stacks 100. Any one or more of the components of the computing device 1600 may include, or be included in, an IC device 1400 (FIG. 14). Any one or more of the components of the computing device 1600 may include, or be included in, an IC device assembly 1500 (FIG. 15).

A number of components are illustrated in FIG. 16 as included in the computing device 1600, but any one or more of these components may be omitted or duplicated, as suitable for the application. In some embodiments, some or all of the components included in the computing device 1600 may be attached to one or more motherboards. In some embodiments, some or all of these components are fabricated onto a single system-on-a-chip (SoC) die.

Additionally, in various embodiments, the computing device 1600 may not include one or more of the components illustrated in FIG. 16, but the computing device 1600 may include interface circuitry for coupling to the one or more components. For example, the computing device 1600 may not include a display device 1612, but may include display device interface circuitry (e.g., a connector and driver circuitry) to which a display device 1612 may be coupled. In another set of examples, the computing device 1600 may not include an audio input device 1616 or an audio output device 1614, but may include audio input or output device interface circuitry (e.g., connectors and supporting circuitry) to which an audio input device 1616 or audio output device 1614 may be coupled.

The computing device 1600 may include a processing device 1602 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1602 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 1600 may include a memory 1604, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1604 may include memory that shares a die with the processing device 1602. This memory may be used as cache memory and may include embedded dynamic random-access memory (eDRAM) or spin transfer torque magnetic random-access memory (STT-MRAM).

In some embodiments, the computing device 1600 may include a communication chip 1606 (e.g., one or more communication chips). For example, the communication chip 1606 may be configured for managing wireless communications for the transfer of data to and from the computing device 1600. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1606 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 1606 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1606 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1606 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1606 may operate in accordance with other wireless protocols in other embodiments. The computing device 1600 may include an antenna 1608 to facilitate wireless communications and/or to receive other wireless communications (such as AM or FM radio transmissions).

In some embodiments, the communication chip 1606 may manage wired communications, such as electrical, optical, or any other suitable communication protocols (e.g., the Ethernet). As noted above, the communication chip 1606 may include multiple communication chips. For instance, a first communication chip 1606 may be dedicated to shorter-range wireless communications such as Wi-Fi or Bluetooth, and a second communication chip 1606 may be dedicated to longer-range wireless communications such as GPS, EDGE, GPRS, CDMA, WiMAX, LTE, EV-DO, or others. In some embodiments, a first communication chip 1606 may be dedicated to wireless communications, and a second communication chip 1606 may be dedicated to wired communications.

The computing device 1600 may include a battery/power circuitry 1610. The battery/power circuitry 1610 may include one or more energy storage devices (e.g., batteries or capacitors) and/or circuitry for coupling components of the computing device 1600 to an energy source separate from the computing device 1600 (e.g., AC line power).

The computing device 1600 may include a display device 1612 (or corresponding interface circuitry, as discussed above). The display device 1612 may include any visual indicators, such as a heads-up display, a computer monitor, a projector, a touchscreen display, a liquid crystal display (LCD), a light-emitting diode display, or a flat panel display, for example.

The computing device 1600 may include an audio output device 1614 (or corresponding interface circuitry, as discussed above). The audio output device 1614 may include any device that generates an audible indicator, such as speakers, headsets, or earbuds, for example.

The computing device 1600 may include an audio input device 1616 (or corresponding interface circuitry, as discussed above). The audio input device 1616 may include any device that generates a signal representative of a sound, such as microphones, microphone arrays, or digital instruments (e.g., instruments having a musical instrument digital interface (MIDI) output).

The computing device 1600 may include an other output device 1618 (or corresponding interface circuitry, as discussed above). Examples of the other output device 1618 may include an audio codec, a video codec, a printer, a wired or wireless transmitter for providing information to other devices, or an additional storage device.

The computing device 1600 may include an other input device 1620 (or corresponding interface circuitry, as discussed above). Examples of the other input device 1620 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1600 may include a global positioning system (GPS) device 1622 (or corresponding interface circuitry, as discussed above). The GPS device 1622 may be in communication with a satellite-based system and may receive a location of the computing device 1600, as known in the art.

The computing device 1600 may include a security interface device 1624. The security interface device 1624 may include any device that provides security features for the computing device 1600 or for any individual components therein (e.g., for the processing device 1602 or for the memory 1604). Examples of security features may include authorization, access to digital certificates, access to items in keychains, etc. Examples of the security interface device 1624 may include a software firewall, a hardware firewall, an antivirus, a content filtering device, or an intrusion detection device.

In some embodiments, the computing device 1600 may include a temperature detection device 1626 and a temperature regulation device 1628.

The temperature detection device 1626 may include any device capable of determining temperatures of the computing device 1600 or of any individual components therein (e.g., temperatures of the processing device 1602 or of the memory 1604). In various embodiments, the temperature detection device 1626 may be configured to determine temperatures of an object (e.g., the computing device 1600, components of the computing device 1600, devices coupled to the computing device, etc.), temperatures of an environment (e.g., a data center that includes, is controlled by, or otherwise associated with the computing device 1600), and so on. The temperature detection device 1626 may include one or more temperature sensors. Different temperature sensors of the temperature detection device 1626 may have different locations within and around the computing device 1600. A temperature sensor may generate data (e.g., digital data) representing detected temperatures and provide the data to another device, e.g., to the temperature regulation device 1628, the processing device 1602, the memory 1604, etc. In some embodiments, a temperature sensor of the temperature detection device 1626 may be turned on or off, e.g., by the processing device 1602 or an external system. The temperature sensor detects temperatures when it is on and does not detect temperatures when it is off. In other embodiments, a temperature sensor of the temperature detection device 1626 may detect temperatures continuously and automatically or detect temperatures at predefined times or at times triggered by an event associated with the computing device 1600 or any components therein.

The temperature regulation device 1628 may include any device configured to change (e.g., decrease) temperatures, e.g., based on one or more target temperatures and/or based on temperature measurements performed by the temperature detection device 1626. A target temperature may be a preferred temperature. A target temperature may depend on a setting in which the computing device 1600 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 1600 can be different. In some embodiments, cooling provided by the temperature regulation device 1628 may be a multi-stage process with temperatures ranging from room temperature to 4K or lower.

In some embodiments, the temperature regulation device 1628 may include one or more cooling devices. Different cooling device may have different locations within and around the computing device 1600. A cooling device of the temperature regulation device 1628 may be associated with one or more temperature sensors of the temperature detection device 1626 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 1600 is satisfied. In response to determining that one or more temperature-related condition associated with the temperature of the computing device 1600 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 1628 may operate with various cooling mechanisms, such as evaporation cooling, radiation cooling, conduction cooling, convection cooling, other cooling mechanisms, or any combination thereof. A cooling device of the temperature regulation device 1628 may include a cooling agent, such as a water, oil, liquid nitrogen, liquid helium, etc. In some embodiments, the temperature regulation device 1628 may be, for example, a dilution refrigerator, a helium-3 refrigerator, or a liquid helium refrigerator. In some embodiments, the temperature regulation device 1628 or any portions thereof (e.g., one or more of the individual cooling devices) may be connected to the computing device 1600 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 1600 (or components thereof) can be reduced, while the computing efficiency may be improved. For example, when the computing device 1600 (or components thereof) operates at lower temperatures, energy dissipation (e.g., heat dissipation) may be reduced. Further, energy consumed by semiconductor components (e.g., energy needed for switching transistors of any of the components of the computing device 1600) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy correlates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 1600 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1600 may be any other electronic device that processes data.

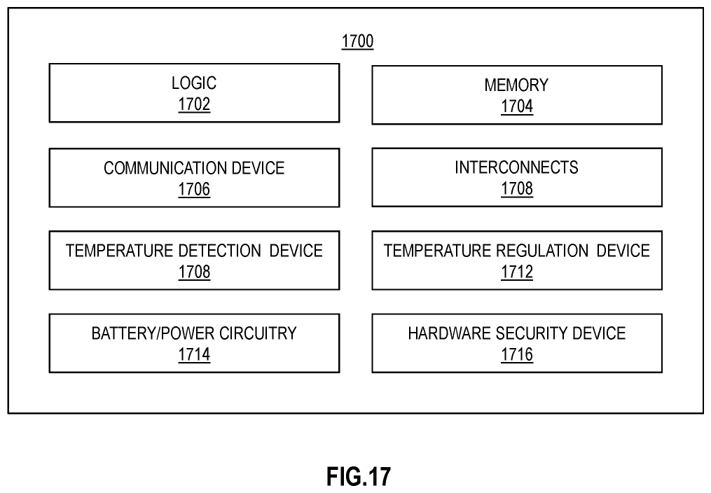

FIG. 17 is a block diagram of an example processing device 1700 that may include one or more transistor gate stacks with dipole layers in accordance with any of the embodiments disclosed herein. For example, any suitable ones of the components of the processing device 1700 may include a die (e.g., the die 1302 (FIG. 13B)) having one or more transistors 120 including one or more transistor gate stacks 100. Any one or more of the components of the processing device 1700 may include, or be included in, an IC device 1400 (FIG. 14). Any one or more of the components of the processing device 1700 may include, or be included in, an IC device assembly 1500 (FIG. 15). Any one or more of the components of the processing device 1700 may include, or be included in, a computing device 1600 (FIG. 16); for example, the processing device 1700 may be the processing device 1602 of the computing device 1600.

A number of components are illustrated in FIG. 17 as included in the processing device 1700, but any one or more of these components may be omitted or duplicated, as suitable for the application. In some embodiments, some or all of the components included in the processing device 1700 may be attached to one or more motherboards. In some embodiments, some or all of these components are fabricated on a single SoC die or coupled to a single support structure, e.g., to a single carrier substrate.

Additionally, in various embodiments, the processing device 1700 may not include one or more of the components illustrated in FIG. 17, but the processing device 1700 may include interface circuitry for coupling to the one or more components. For example, the processing device 1700 may not include a memory 1704, but may include display device interface circuitry (e.g., a connector and driver circuitry) to which a memory 1704 may be coupled.

The processing device 1700 may include logic circuitry 1702 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 1702 may include one or more circuits responsible for read/write operations with respect to the data stored in the memory 1704. To that end, the logic circuitry 1702 may include one or more I/O ICs configured to control access to data stored in the memory 1704.

In some embodiments, the logic circuitry 1702 may include one or more high-performance compute dies, configured to perform various operations with respect to data stored in the memory 1704 (e.g., arithmetic and logic operations, pipelining of data from one or more memory dies of the memory 1704, and possibly also data from external devices/chips). In some embodiments, the logic circuitry 1702 may be configured to only control I/O access to data but not perform any operations on the data. In some embodiments, the logic circuitry 1702 may implement ICs configured to implement I/O control of data stored in the memory 1704, assemble data from the memory 1704 for transport (e.g., transport over a central bus) to devices/chips that are either internal or external to the processing device 1700, etc. In some embodiments, the logic circuitry 1702 may not be configured to perform any operations on the data besides I/O and assembling for transport to the memory 1704.

The processing device 1700 may include a memory 1704, which may include one or more ICs configure to implement memory circuitry (e.g., ICs implementing one or more of memory devices, memory arrays, control logic configured to control the memory devices and arrays, etc.). In some embodiments, the memory 1704 may be implemented substantially as described above with reference to the memory 1604 (FIG. 16). In some embodiments, the memory 1704 may be a designated device configured to provide storage functionality for the components of the processing device 1700 (i.e., local), while the memory 1604 may be configured to provide system-level storage functionality for the entire computing device 1600 (i.e., global). In some embodiments, the memory 1704 may include memory that shares a die with the logic circuitry 1702.

In some embodiments, the memory 1704 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 1704 may be a memory that is not divided into hierarchical layer or levels in terms of access of its data.

In some embodiments, the memory 1704 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m₁, m₂, . . . , mᵢₙ) in which each member mᵢ is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 1704 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 1704 may be arranged.

The processing device 1700 may include a communication device 1706, which may be implemented substantially as described above with reference to the communication chip 1606 (FIG. 16). In some embodiments, the communication device 1706 may be a designated device configured to provide communication functionality for the components of the processing device 1700 (i.e., local), while the communication chip 1606 may be configured to provide system-level communication functionality for the entire computing device 1600 (i.e., global).

The processing device 1700 may include interconnects 1708, which may include any element or device that includes an electrically conductive material for providing electrical connectivity to one or more components of, or associated with, a processing device 1700 or/and between various such components. Examples of the interconnects 1708 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 1700 may include a temperature detection device 1710 which may be implemented substantially as described above with reference to the temperature detection device 1626 (FIG. 16) but configured to determine temperatures on a more local scale, i.e., of the processing device 1700 of components thereof. In some embodiments, the temperature detection device 1710 may be a designated device configured to provide temperature detection functionality for the components of the processing device 1700 (i.e., local), while the temperature detection device 1626 may be configured to provide system-level temperature detection functionality for the entire computing device 1600 (i.e., global).

The processing device 1700 may include a temperature regulation device 1712 which may be implemented substantially as described above with reference to the temperature regulation device 1628 (FIG. 16) but configured to regulate temperatures on a more local scale, i.e., of the processing device 1700 of components thereof. In some embodiments, the temperature regulation device 1712 may be a designated device configured to provide temperature regulation functionality for the components of the processing device 1700 (i.e., local), while the temperature regulation device 1628 may be configured to provide system-level temperature regulation functionality for the entire computing device 1600 (i.e., global).

The processing device 1700 may include a battery/power circuitry 1714 which may be implemented substantially as described above with reference to the battery/power circuitry 1610 (FIG. 16). In some embodiments, the battery/power circuitry 1714 may be a designated device configured to provide battery/power functionality for the components of the processing device 1700 (i.e., local), while the battery/power circuitry 1610 may be configured to provide system-level battery/power functionality for the entire computing device 1600 (i.e., global).

The processing device 1700 may include a hardware security device 1716 which may be implemented substantially as described above with reference to the security interface device 1624 (FIG. 16). In some embodiments, the hardware security device 1716 may be a physical computing device configured to safeguard and manage digital keys, perform encryption and decryption functions for digital signatures, authentication, and other cryptographic functions. In some embodiments, the hardware security device 1716 may include one or more secure cryptoprocessors chips.

The above description of illustrated implementations of the disclosure, including what is described in the Abstract, is not intended to be exhaustive or to limit the disclosure to the precise forms disclosed. For example, while the above descriptions of the drawings are provided with respect to the reference numeral “104” representing the dipole layer and the reference numeral “106” representing the high-k dielectric, in other embodiments, the designations of these reference numerals and the associated descriptions may be reversed. In such embodiments, the drawings may remain the same, but the reference numeral “104” may represent the high-k dielectric while the reference numeral “106” may represent the dipole layer. Thus, in such embodiments, the multilayer gate oxide 110 disposed between the gate electrode material 108 and the channel material 102 is such that the dipole layer is between the gate electrode material and the channel material, and the high-k dielectric is between the dipole layer and the channel material.

The following paragraphs provide various examples of the embodiments disclosed herein.

Example 1 provides an IC device that includes a transistor gate-channel arrangement that includes a channel material and a transistor gate stack, where the transistor gate stack includes a gate electrode material, a high-k dielectric between the gate electrode material and the channel material, and a dipole layer between the high-k dielectric material and the channel material, where the dipole layer is a layer of a material having pairs of equal and opposite electric charges which charges readily separate upon application of an electric field so that charges of opposite signs are separated by a small distance (e.g., a distance of about 0.1-1 nanometers). Including a dipole layer between a high-k dielectric and a channel material allows improving (e.g., increasing) the effective k-value of the high-k dielectric. In turn, this may allow implementing thinner layers of high-k dielectrics or high-k dielectric with suboptimal properties.

Example 2 provides the IC device according to example 1, where the high-k dielectric has a thickness below about 1.5 nanometers.

Example 3 provides the IC device according to examples 1 or 2, where the dipole layer has a thickness below about 1 nanometer.

Example 4 provides the IC device according to any one of examples 1-3, where a stack of the high-k dielectric and the dipole layer has a thickness below about 2 nanometers.

Example 5 provides the IC device according to any one of examples 1-4, where the dipole layer includes oxygen and one or more rare-earth elements (e.g., the dipole layer may include one or more rare-earth oxides such as yttrium oxide and/or lanthanum oxide).

Example 6 provides the IC device according to any one of examples 1-5, where the gate electrode material is in contact with the high-k dielectric.

Example 7 provides the IC device according to any one of examples 1-6, where the high-k dielectric is in contact with the dipole layer.

Example 8 provides the IC device according to any one of examples 1-7, where the dipole layer is in contact with the channel material.

Example 9 provides the IC device according to any one of examples 1-7, further including a passivation layer between the dipole layer and the channel material, where the dipole layer is in contact with the passivation layer and the passivation layer is in contact with the channel material.

Example 10 provides the IC device according to example 9, where the channel material is a non-oxide semiconductor and the passivation layer includes an oxide of the non-oxide semiconductor. Such a passivation layer may spontaneously form between the dipole layer and the channel material as an oxide of the native semiconductor of the channel material.

Example 11 provides the IC device according to any one of examples 1-9, where the channel material includes IGZO, tin oxide, antimony oxide, indium oxide, indium tin oxide, titanium oxide, zinc oxide, indium zinc oxide, gallium oxide, titanium oxynitride, ruthenium oxide, or tungsten oxide.

Example 12 provides the IC device according to any one of examples 1-9, where the channel material includes a semiconductor having an average grain size smaller than about 1 millimeter.

Example 13 provides the IC device according to any one of examples 1-9, where the channel material includes a semiconductor having an average grain size larger than about 1 millimeter.

Example 14 provides the IC device according to any one of examples 1-13, where the high-k dielectric includes hafnium oxide.

Example 15 provides the IC device according to any one of examples 1-14, where the high-k dielectric includes zirconium oxide, aluminum oxide, tantalum oxide, tantalum silicon oxide, hafnium silicon oxide, or lanthanum oxide.

Example 16 provides the IC device according to any one of examples 1-15, where the IC device includes a transistor and the transistor gate-channel arrangement is a part of the transistor.

Example 17 provides the IC device according to example 17, where the transistor further includes a source region and a drain region.

Example 18 provides the IC device according to any one of examples 16-17, where the transistor has a gate length between 3 and 30 nanometers.

Example 19 provides the IC device according to any one of examples 16-18, where the channel material is coplanar with the source region and the drain region.

Example 20 provides the IC device according to any one of examples 16-18, where the channel material is shaped as a fin, the dipole layer wraps around a top portion of the fin, and the high-k dielectric wraps around the dipole layer.

Example 21 provides the IC device according to any one of examples 16-18, where the channel material is shaped as a nanoribbon, the dipole layer wraps around the nanoribbon, and the high-k dielectric wraps around the dipole layer.

Example 22 provides the IC device according to example 21, where the dipole layer wraps entirely around the nanoribbon and the high-k dielectric wraps entirely around the dipole layer.

Example 23 provides an IC device that includes a transistor gate-channel arrangement that includes a channel material and a transistor gate stack, where the transistor gate stack includes a gate electrode material, a dipole layer between the gate electrode material and the channel material, and a high-k dielectric between the dipole layer and the channel material.

Example 24 provides the IC device according to example 23, where the high-k dielectric has a thickness below about 1.5 nanometers.

Example 25 provides the IC device according to examples 23 or 24, where the dipole layer has a thickness below about 1 nanometer.

Example 26 provides the IC device according to any one of examples 23-25, where a stack of the high-k dielectric and the dipole layer has a thickness below about 2 nanometers.

Example 27 provides the IC device according to any one of examples 23-26, where the dipole layer includes oxygen and one or more rare-earth elements (e.g., the dipole layer may include one or more rare-earth oxides such as yttrium oxide and/or lanthanum oxide).

Example 28 provides the IC device according to any one of examples 23-27, where the gate electrode material is in contact with the high-k dielectric.

Example 29 provides the IC device according to any one of examples 23-28, where the high-k dielectric is in contact with the dipole layer.

Example 30 provides the IC device according to any one of examples 23-29, where the dipole layer is in contact with the channel material.

Example 31 provides the IC device according to any one of examples 23-30, where the channel material includes IGZO, tin oxide, antimony oxide, indium oxide, indium tin oxide, titanium oxide, zinc oxide, indium zinc oxide, gallium oxide, titanium oxynitride, ruthenium oxide, or tungsten oxide.

Example 32 provides the IC device according to any one of examples 23-31, where the channel material includes a semiconductor having an average grain size smaller than about 1 millimeter.

Example 33 provides the IC device according to any one of examples 23-30, where the channel material includes a semiconductor having an average grain size larger than about 1 millimeter.

Example 34 provides the IC device according to any one of examples 23-33, where the high-k dielectric includes hafnium oxide.

Example 35 provides the IC device according to any one of examples 23-34, where the high-k dielectric includes zirconium oxide, aluminum oxide, tantalum oxide, tantalum silicon oxide, hafnium silicon oxide, or lanthanum oxide.

Example 36 provides the IC device according to any one of examples 23-35, where the IC device includes a transistor and the transistor gate-channel arrangement is a part of the transistor.

Example 37 provides the IC device according to example 36, where the transistor further includes a source region and a drain region.

Example 38 provides the IC device according to any one of examples 36-37, where the transistor has a gate length between 3 and 30 nanometers.

Example 39 provides the IC device according to any one of examples 36-38, where the channel material is coplanar with the source region and the drain region.

Example 40 provides the IC device according to any one of examples 36-38, where the channel material is shaped as a fin, the high-k dielectric wraps around a top portion of the fin, and the dipole layer wraps around the high-k dielectric.

Example 41 provides the IC device according to any one of examples 36-38, where the channel material is shaped as a nanoribbon, the high-k dielectric wraps around the nanoribbon, and the dipole layer wraps around the high-k dielectric.

Example 42 provides the IC device according to example 41, where the high-k dielectric wraps entirely around the nanoribbon and the dipole layer wraps entirely around the high-k dielectric.

Example 43 provides an IC package, including an IC die, including an IC device according to any one of the preceding examples (e.g., any one of examples 1-42); and a further component, coupled to the IC die.

Example 44 provides the IC package according to example 43, where the further component is one of a package substrate, an interposer, or a further IC die.

Example 45 provides the IC package according to any one of examples 43-44, where the further component is coupled to the IC die via one or more first level interconnects, and the one or more first level interconnects include one or more solder bumps, solder posts, or bond wires.

Example 46 provides an electronic device, including a carrier substrate; and one or more of the IC devices according to any one of the preceding examples and/or the IC package according to any one of the preceding examples, coupled to the carrier substrate.

Example 47 provides the electronic device according to example 46, where the carrier substrate is a motherboard.

Example 48 provides the electronic device according to example 46, where the carrier substrate is a PCB.

Example 49 provides the electronic device according to any one of examples 46-48, where the electronic device is a wearable electronic device (e.g., a smart watch) or handheld electronic device (e.g., a mobile phone).

Example 50 provides the electronic device according to any one of examples 46-49, where the electronic device further includes one or more communication chips and an antenna.

Example 51 provides the electronic device according to any one of examples 46-50, where the electronic device is memory device.

Example 52 provides the electronic device according to any one of examples 46-50, where the electronic device is one of an RF transceiver, a switch, a power amplifier, a low-noise amplifier, a filter, a filter bank, a duplexer, an upconverter, or a downconverter of an RF communications device, e.g., of an RF transceiver.

Example 53 provides the electronic device according to any one of examples 46-50, where the electronic device is a computing device.

Example 54 provides the electronic device according to any one of examples 46-53, where the electronic device is included in a base station of a wireless communication system.

Example 55 provides the electronic device according to any one of examples 46-53, where the electronic device is included in a user equipment device (i.e., a mobile device) of a wireless communication system.

Example 56 provides a method of manufacturing an IC device that includes a transistor, the method including providing a channel material; providing a dipole layer over a portion of the channel material; providing a high-k dielectric over at least a portion of the dipole layer; and providing a gate electrode material over at least a portion of the high-k dielectric.

Example 57 provides the method according to example 56, where providing the dipole layer includes performing ALD, PVD, or CVD of the dipole layer.

Example 58 provides the method according to any one of examples 56-57, where the gate electrode material, the high-k dielectric, and the dipole layer form a transistor gate stack of the transistor, and the method further includes providing a source region and a drain region in either side of the transistor gate stack.

Example 59 provides the method according to any one of examples 56-58, where the dipole layer at least partially wraps around the channel material.

Example 60 provides the method according to example 59, where the dipole layer encircles the channel material.

Example 61 provides a method of manufacturing an IC device that includes a transistor, the method including providing a channel material; providing a high-k dielectric over a portion of the channel material; providing a dipole layer over at least a portion of the high-k dielectric; and providing a gate electrode material over at least a portion of the dipole layer.

Example 62 provides the method according to claim 61, where providing the dipole layer comprises performing ALD, PVD, or CVD of the dipole layer.

Example 63 provides the method according to any one of claims 61-62, where the gate electrode material, the high-k dielectric, and the dipole layer form a transistor gate stack of the transistor, and the method further includes providing a source region and a drain region in either side of the transistor gate stack.

Example 64 provides the method according to any one of claims 61-63, where the dipole layer at least partially wraps around the channel material.

Example 65 provides the method according to claim 64, where the dipole layer encircles the channel material.

1. An integrated circuit (IC) device, comprising:
a channel material; and
a transistor gate stack,
wherein the transistor gate stack includes:
a gate electrode material,
a high-k dielectric between the gate electrode material and the channel material, and
a dipole layer between the high-k dielectric material and the channel material.

2. The IC device according to claim 1, wherein the high-k dielectric has a thickness below about 1.5 nanometers.

3. The IC device according to claim 1, wherein the dipole layer has a thickness below about 1 nanometer.

4. The IC device according to claim 1, wherein a stack of the high-k dielectric and the dipole layer has a thickness below about 2 nanometers.

5. The IC device according to claim 1, wherein the dipole layer includes oxygen and one or more rare-earth elements.

6. The IC device according to claim 1, wherein the gate electrode material is in contact with the high-k dielectric.

7. The IC device according to claim 1, wherein the high-k dielectric is in contact with the dipole layer.

8. The IC device according to claim 1, wherein the dipole layer is in contact with the channel material.

9. The IC device according to claim 1, further comprising a passivation layer between the dipole layer and the channel material, wherein the dipole layer is in contact with the passivation layer and the passivation layer is in contact with the channel material.

10. The IC device according to claim 9, wherein the channel material is a non-oxide semiconductor and the passivation layer includes an oxide of the non-oxide semiconductor.

11. The IC device according to claim 1, wherein the channel material includes indium gallium zinc oxide (IGZO), tin oxide, antimony oxide, indium oxide, indium tin oxide, titanium oxide, zinc oxide, indium zinc oxide, gallium oxide, titanium oxynitride, ruthenium oxide, or tungsten oxide.

12. The IC device according to claim 1, wherein the channel material includes a semiconductor having an average grain size larger than about 1 millimeter.

13. The IC device according to claim 1, wherein:
the IC device includes a transistor, and
the transistor includes the channel material and the transistor gate stack.

14. The IC device according to claim 13, wherein the transistor further includes a source region and a drain region, and the channel material is coplanar with the source region and the drain region.

15. The IC device according to claim 13, wherein the channel material is a fin, the dipole layer wraps around a top portion of the fin, and the high-k dielectric wraps around the dipole layer.

16. The IC device according to claim 13, wherein the channel material is a nanoribbon, the dipole layer wraps around the nanoribbon, and the high-k dielectric wraps around the dipole layer.

17. An integrated circuit (IC) device, comprising:
a channel material; and
a transistor gate stack,
wherein the transistor gate stack includes:
a gate electrode material,
a dipole layer between the gate electrode material and the channel material, and
a high-k dielectric between the dipole layer and the channel material.

18. The IC device according to claim 17, wherein a stack of the high-k dielectric and the dipole layer has a thickness below about 2 nanometers.

19. A method of manufacturing a transistor, the method comprising:
providing a channel material;
providing a dipole layer over a portion of the channel material;
providing a high-k dielectric over at least a portion of the dipole layer; and
providing a gate electrode material over at least a portion of the high-k dielectric.

20. The method according to claim 19, wherein providing the dipole layer comprises performing atomic layer deposition, physical vapor deposition, or chemical vapor deposition of the dipole layer.
